(19) United States
(12) Patent Application Publication
(10) Pub. No.: US 2004/0154529 A1
(43) Pub. Date: Aug. 12, 2004

(54) Substrate holder, method for producing substrate holder, and method for producing mold

(76) Inventors: Tatsuki Nogiwa, Yawata (JP); Hironori Uemura, Kuze-gun (JP)

Correspondence Address: WENDEROTH, LIND & PONACK, L.L.P., 2033 K STREET N. W., SUITE 800, WASHINGTON, DC, 20006-1021, US

(21) Appl. No.: 10/772,355

(22) Filed: Feb. 6, 2004

(30) Foreign Application Priority Data
Feb. 7, 2003 (JP) 2003-31094

(51) Int. Cl. C30B 1/00

(52) U.S. Cl. 117/200

(57) ABSTRACT

A pallet 1 for holding an FPC 9 in order to mount electronic components thereon includes a first adhesive holding region 21 in a peripheral portion and a second adhesive holding region 22 in a central portion. The first adhesive holding region 21 has a relatively low tackiness, whereas the second adhesive holding region 22 has a higher tackiness than that of the first adhesive holding region 21. The pallet 1 has through holes 31 for receiving push-up pins to be used when peeling off the FPC 9, and air outlets 32 for assisting in the peeling.

### BACKGROUND OF THE INVENTION

1. Field of the Invention

The present invention relates to a technique for holding a circuit board, and more particularly to a technique for holding a flexible circuit board when mounting electronic components on the flexible circuit board.

2. Description of the Background Art

In recent years, sheet-like flexible printed circuit boards (hereinafter “FPCs”) are being used in small electronic devices such as mobile phones, PDAs (Personal Data Assistants), and notebook-type computers. An FPC may comprise various wiring patterns formed on a resin sheet, with a variety of electronic components, e.g., ICs, capacitors, resistors, coils, and/or connectors being formed on the wiring patterns. Use of an FPC for electronic devices allows the circuit board to be flexibly disposed within an electronic device, an also allows for downsizing of the electronic device.

An exemplary technique is proposed in Japanese Patent Laid-Open Publication No. 2002-232197, in which an adhesive holding layer is provided on a base plate. In this technique, an FPC is adhered to an adhesive holding layer which is provided on a base plate. The resultant composite of the FPC and the base plate is treated in the same manner as a usual circuit board.

In the above example, a region of the base plate in which the adhesive holding layer is provided for adhering an FPC thereto is referred to as an “adhesive holding region”, as opposed to the adhesive holding layer itself which is provided in the adhesive holding region. When electronic components must be mounted on an FPC which is adhered to a base plate, it is imperative that the shape of the adhesive holding layer (adhesive holding region) and the adhesive holding layer's adhesion ability to the FPC be optimally designed. In the case where electronic components are mounted on an FPC by using solder paste, a series of steps are performed to effectuate the mounting, including: screen printing of solder paste onto the FPC; installation of the electronic components; and a reflow (heating and cooling).

If a highly adhesive material is present in regions of the base plate other than the adhesive holding region (hereinafter “non-adhesive holding regions”), a screen mask which is used during screen printing may adhere also to the non-adhesive holding regions. Moreover, since the FPC is not meant to adhere to the non-adhesive holding regions as described above, adhesion between the FPC and the non-adhesive holding regions would be highly problematic in the mounting process.

In the case where the adhesive holding layer has a poor adhesion ability, it would be difficult to hold the FPC onto the base plate through adhesion, against the wind pressure of hot air circulation during a reflow. On the other hand, in the case where the adhesive holding layer has an excessive adhesion ability, a substantial force would be applied to the FPC when it is to be taken off the adhesive material, even if no adhesive material is present in the non-adhesive holding regions. As a result, the FPC may not be able to be properly removed from the base plate.

### SUMMARY OF THE INVENTION

Therefore, an object of the present invention is to provide a technique which facilitates the handling of a circuit board which is retained through adhesion.

The present invention has the following features to attain the object mentioned above. The present invention is directed to a substrate holder for holding a circuit board, comprising: a main body; and a holding surface formed on the main body for allowing a circuit board to adhere to the holding surface, wherein the holding surface includes: a first adhesive holding region for holding the circuit board with a first tackiness; and a second adhesive holding region for holding the circuit board with a second tackiness which is different from the first tackiness, such that the first and second adhesive holding regions hold the circuit board in cooperation.

According to the present invention, an adhesive holding region which is composed of two adhesive holding layers having different levels of tackiness facilitates the handling of a circuit board in accordance with the presence or absence of components mounted on an FPC.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a pallet according to a first embodiment of the present invention;

FIG. 2 is a cross-sectional view of the pallet shown in FIG. 1, taken at line II-II;

FIG. 3 is a plan view illustrating an FPC being held by the pallet shown in FIG. 1;

FIG. 4 is a partial elevation view showing a portion of a mounting system for mounting components on a pallet according to an embodiment of the present invention;

FIG. 5 is a partial elevation view showing a different portion of the mounting system shown in FIG. 4;

FIG. 6 is an explanatory diagram illustrating a preliminary peeling process which occurs when the pickup mechanism as shown in FIG. 5 receives an FPC from a pallet;

FIG. 7 is an explanatory diagram illustrating a full peeling process which occurs when the pickup mechanism as shown in FIGS. 4 and 5 receives an FPC from a pallet;

FIG. 8 is a flowchart illustrating a flow of processes of producing the pallet shown in FIG. 1;

FIG. 9 is an explanatory diagram illustrating a method of producing the pallet shown in FIG. 1;

FIG. 10 is an explanatory diagram illustrating a method of producing the pallet shown in FIG. 1;

FIG. 11 is a flowchart illustrating a flow of processes of producing a mold shown in FIGS. 9 and 10;

FIG. 12 is an explanatory diagram illustrating a method of producing a mold shown in FIGS. 9 and 10;

FIG. 13 is an explanatory diagram illustrating a method of producing a mold shown in FIGS. 9 and 10;

FIG. 14 is a plan view illustrating a pallet according to a second embodiment the present invention pallet;

FIG. 15 is a plan view illustrating an unit FPC piece being held by the pallet shown in FIG. 14;

FIG. 16 is a plan view illustrating a plurality of unit FPC pieces shown in FIG. 15 being held by the pallet shown in FIG. 14;

FIG. 17 is a cross-sectional view illustrating a pallet according to a third embodiment of the present invention;

FIG. 18 is a plan view illustrating a pallet according to a fourth embodiment the present invention;

FIG. 19 is across-sectional view illustrating a pallet according to a fifth embodiment of the present invention;

FIG. 20 is an explanatory diagram illustrating a method of producing the pallet shown in FIG. 19; and

FIG. 21 is a cross-sectional view illustrating a pallet according to a sixth embodiment of the present invention.

### DESCRIPTION OF THE PREFERRED EMBODIMENTS

(First Embodiment)

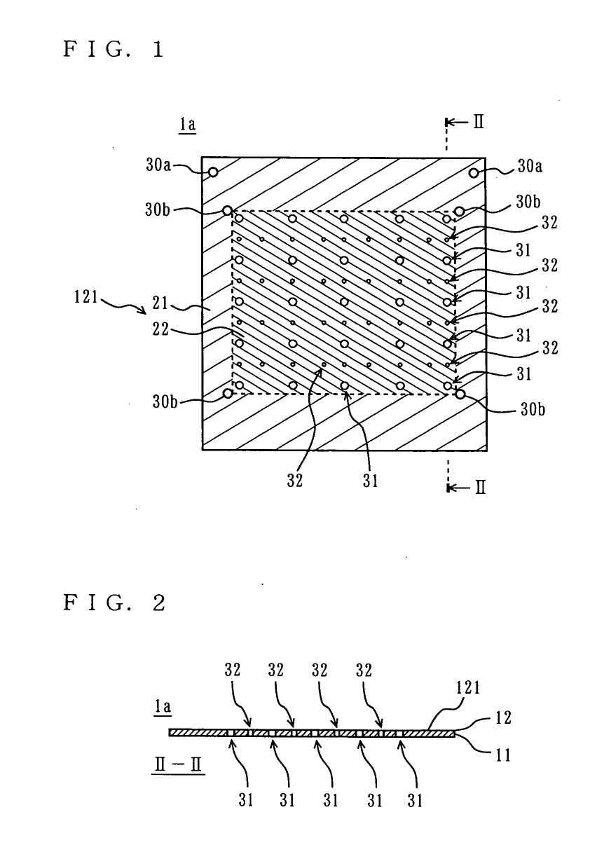

Hereinafter, a substrate holder according to an embodiment of the present invention will be described with reference to FIGS. 1 to 13. As shown in FIG. 1, the substrate holder according to the present embodiment is implemented as a pallet 1a for carrying an FPC. FIG. 2 is a cross-sectional view of the pallet 1a shown in FIG. 1, taken at line II-II. As can be seen from FIG. 2, the pallet 1a has a structure such that an adhesive holding layer 12 formed of an adhesive material is glued onto a planar base plate 11, which serves as a main body. The base plate 11 may be a metal having a good thermal conductivity, e.g., aluminum or magnesium (which may also be any other material having a high stiffness), or a resin such as glass epoxy resin. As the adhesive material, silicone rubber is preferably used in the case where heat resistance is required. In the case where heat resistance is not a requirement, polyurethane rubber or the like may be used as the adhesive material.

The upper face of the pallet 1a, on which the adhesive holding layer 12 is formed, constitutes a holding surface 121 on which an FPC is to be held through adhesion. As shown in FIG. 1, the holding surface 121 has in its periphery a first adhesive holding region 21 of a low tackiness. In a central portion, the holding surface 121 has a second adhesive holding region 22 having a higher tackiness than that of the first adhesive holding region 21. In cooperation with the first adhesive holding region 21, the second adhesive holding region 22 hold an FPC through adhesion. FIG. 1 conveniently shows different tackinesses by different types of oblique hatching. As used herein, a “tackiness” is a value corresponding to a force which is required to peel off an object which has adhered to the adhesive holding layer under certain conditions, and thus serves as a measure of adhesion.

The first adhesive holding region 21 and the second adhesive holding region 22 are provided within the same plane so as to form fractions of the surface of the adhesive holding layer 12, and are composed of the same adhesive material. By thus providing the adhesive holding regions 21 and 22 within the same plane, it becomes easy to form the adhesive holding regions 21 and 22, as will be described later.

The difference between the tackiness of the first adhesive holding region 21 and the tackiness of the second adhesive holding region 22 can be realized by varying the surface coarseness of the adhesive material. With reference to Table 1, the relationship between surface coarseness and tackiness will be described. Table 1 shows a force value which is required to peel a piece of aluminum (having a contact surface of 1 cm²) off an adhesive holding layer, which was once caused to adhere to the adhesive holding layer while applying a force of 500 gf for about three seconds, the aluminum piece having been anodized and then mirror-surfaced in advance. From Table 1, it can be seen that tackiness increases with reduced surface coarseness.

TABLE 1

| | surface coarseness | | peeling force (gf) |
|---|---|---|---|
| mirror face | | | 750 |
| | 1 | S | 640 |
| | 1.6 | S | 570 |

As shown in FIG. 1, through holes 30a for positioning purposes are formed in the corners of the pallet 1a. Furthermore, as shown in FIGS. 1 and 2, the second adhesive holding region 22 also has a multitude of through holes 31 and air outlets 32 formed therein. Into the through holes 31, push-up pins are inserted to assist in the peeling of an FPC which is being held in the pallet 1a. The air outlets 32 are through holes through which air is supplied at the time of release. Near the four corners of the first adhesive holding region 21, through holes 30b are formed to be used for the positioning the FPC to be held.

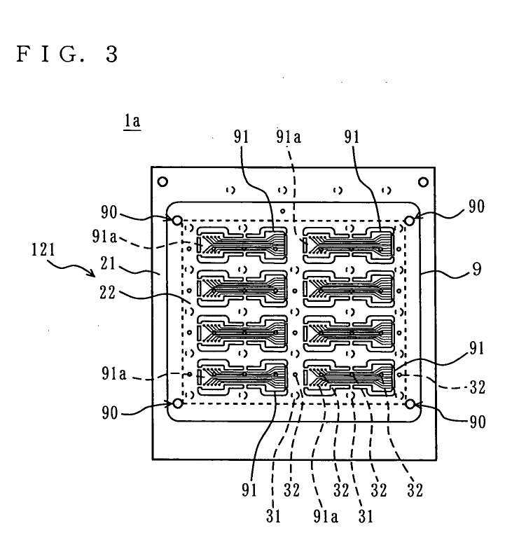

FIG. 3 illustrates an FPC 9 being held in the pallet 1a. Note that a plurality of unit FPC pieces 91 are wired onto the FPC 9. Each unit FPC piece 91 has a mount region 91a in which an IC package is to be mounted (other examples of mountable objects include bear IC chips, capacitors, resistors, coils, and/or connectors: hereinafter such elements will be collectively referred to as “electronic components”). In the four corners of the FPC 9, positioning holes 90 are formed so as to come into an overlapping relationship with the through holes 30b for the FPC as shown in FIG. 1. The peripheral portion of the FPC 9 will overlap with the first adhesive holding region 21, whereas the second adhesive holding region 22 will overlap with a central portion of the FPC 9. The through holes 31 for the push-up pins are disposed so as to come between the unit FPC pieces 91. The air outlets 32 are disposed so as to come directly under the unit FPC pieces 91 or between the through holes 31.

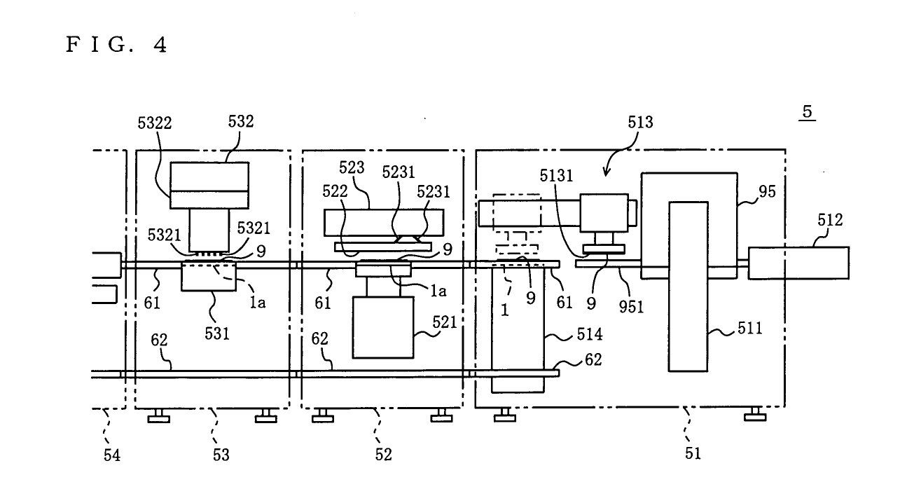

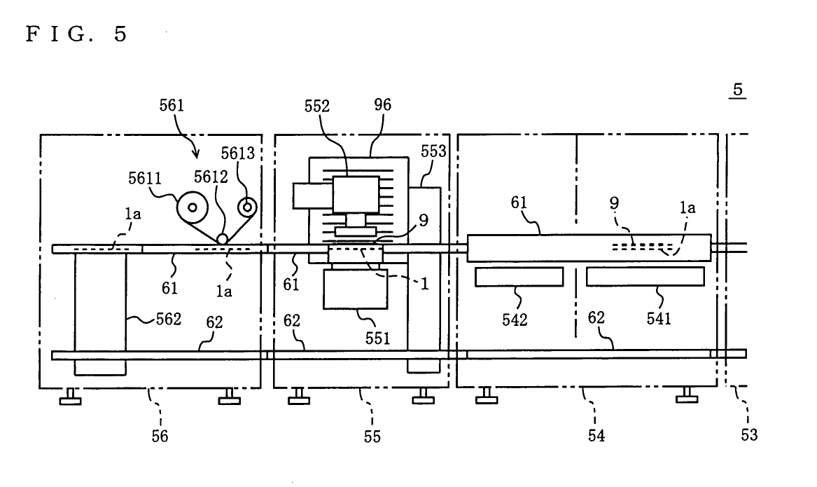

FIGS. 4 and 5 illustrate a mounting system 5 which mounts electronic components in the mount region 91a of each unit FPC piece 91 while the FPC 9 is held in the pallet 1a. From upstream, the mounting system 5 includes, in this order: a loader apparatus 51 which places the FPC 9 on the pallet 1a; a printing apparatus 52 which prints solder paste on the FPC 9; a mounting apparatus 53 which mounts electronic components onto the FPC 9; a reflow apparatus 54 which melts and solidifies the solder paste to fix the electronic components to the FPC 9; an unloader apparatus 55 which peels the FPC 9 off the pallet 1a; and a cleaning apparatus 56 which cleans the pallet 1a.

Note that FIG. 4 shows the loader apparatus 51, the printing apparatus 52, the mounting apparatus 53, and an end portion of the reflow apparatus 54, while FIG. 5 shows an end portion of the mounting apparatus 53, the reflow apparatus 54, the unloader apparatus 55, and the cleaning apparatus 56. In a substantial center of each apparatus, an outgoing conveyor 61 for carrying away the pallet 1a is provided. In a lower part of each apparatus, an incoming conveyor 62 for carrying in the pallet 1a is provided.

At the loader apparatus 51, a plurality of trays 951 are accommodated in a container 95 while stacked on top of one another, with an FPC 9 being placed on each tray 951. The loader apparatus 51 includes: an elevation mechanism 511 for moving up or down the container 95; a protrusion mechanism 512 for pushing out or pulling in a single tray 951 from/to the container 95; a pickup mechanism 513 for picking up the protruded tray 951 via suction; and a pallet moving mechanism 514 for moving the pallet 1a from an arriving end of the incoming conveyor 62 to a leaving end of the outgoing conveyor 61.

The pickup mechanism 513 has a holding surface 5131 against which the FPC 9 is held. The holding surface 5131 constitutes a plane with a multitude of suction apertures formed therein. The pickup mechanism 513 picks up the FPC 9 from the tray 951 via suction, and thereafter places the FPC 9 onto the pallet 1a, which in turn is on the conveyor 61. Specifically, while positioning the FPC 9 on the basis of the through holes 30b in the pallet 1a and the holes 90 in the FPC 9, the holding surface 5131 is lowered so as to press the entire FPC 9 against the pallet 1a with a predetermined pressure. As a result, the entire FPC 9 sticks to the adhesive holding layer 12 of the pallet 1a. The pallet 1a thus holding the FPC 9 is carried to the printing apparatus 52 by the conveyor 61.

The printing apparatus 52 includes: an elevation mechanism 521 for thrusting the pallet 1a up toward a screen mask 522, while the pallet 1a is held in place on the basis of the positioning through holes 30a (i.e., by inserting pins therein; see FIG. 1); and a print mechanism 523 for allowing solder paste on the screen mask 522 to move back and forth with an action of a squeegee 5231. As the print mechanism 523 moves the squeegee 5231 back and forth, with the FPC 9 on the pallet 1a being abutted against the screen mask 522, the solder paste becomes attached to the FPC 9 through apertures formed in the screen mask 522. The FPC 9 with the solder paste printed thereon is then lowered together with the pallet 1a, and thereafter is carried by the conveyor 61 to the mounting apparatus 53.

As shown in FIG. 3, a region of the adhesive holding layer 12 of the pallet 1a in which the FPC 9 is not adhered corresponds to the first adhesive holding region 21 having a relatively low tackiness. Therefore, the screen mask 522 is only weakly stuck to the first adhesive holding region 21 during printing, thus facilitating the contacting and parting between the screen mask 522 and the pallet 1a. Moreover, by forming the adhesive holding layer 12 in a uniform fashion on the base plate 11 independently of the layout of the unit FPC pieces 91, the regions on the front or back face of the FPC 9 in which electrodes are exposed, or how the insulative regions are distributed (or more precisely, by ensuring that the adhesive holding layer is continuously present with at least a certain width over the entire moving range of the squeegee 5231), it becomes possible to prevent deformation of the screen mask 522 due to the pressurization by the squeegee 5231, whereby degradation in the printing quality can be prevented.

The mounting apparatus 53 includes: a retention mechanism 531 for retaining the pallet 1a in place on the basis of the through holes 30a; and a mount mechanism 532 for mounting electronic components onto the FPC 9, which in itself is on the pallet 1a. The mount mechanism 532 includes a plurality of nozzles 5321 for sucking electronic components, and a nozzle moving mechanism 5322 which moves the nozzles 5321 in a horizontal plane as well as in a vertical direction. As such, the mount mechanism 532 receives electronic components from a supply mechanism which is not shown (a mechanism for arranging electronic components on a tape or a tray in preparation for the mounting), and mounts the electronic components to the solder paste on the FPC 9. By the conveyor 61, the FPC 9 with the electronic components mounted thereto is carried together with the pallet 1a, to the reflow apparatus 54 shown in FIG. 5.

The reflow apparatus 54 includes: a heating section 541 for preheating and fully heating the FPC 9, which is being carried by the conveyor 61 while being held onto the pallet 1a; and a cooling section 542 for cooling the FPC 9 with air. Thus, the FPC 9 is heated and then cooled while being carried, whereby the solder paste is melted and then solidified to fix the electronic components to the FPC 9. As shown in FIG. 3, since the entire FPC 9 is adhered to the adhesive holding layer 12 of the pallet 1a, the FPC 9 is prevented from peeling off the adhesive holding layer 12, in part or in whole, even if heating with a hot blow of air and cooling with a cold blow of air are performed. After this reflow process, the FPC 9 is carried together with the pallet 1a to the unloader apparatus 55.

The unloader apparatus 55 includes: a retention mechanism 551 for retaining the pallet 1a; a pickup mechanism 552 for receiving the FPC 9 from the pallet 1a; an elevation mechanism 553 for moving up and down the container 96 containing the FPCs 9; and a protrusion mechanism (not shown) for pushing out or pulling in a tray from/to the container 96. A plurality of trays are accommodated in the container 96 while stacked on top of one another. The protrusion mechanism pushes forward a tray, and the pickup mechanism 552 receives the FPC 9 from the pallet 1a and places the FPC 9 on the tray. Thereafter, the protrusion mechanism retracts the tray into the container 96.

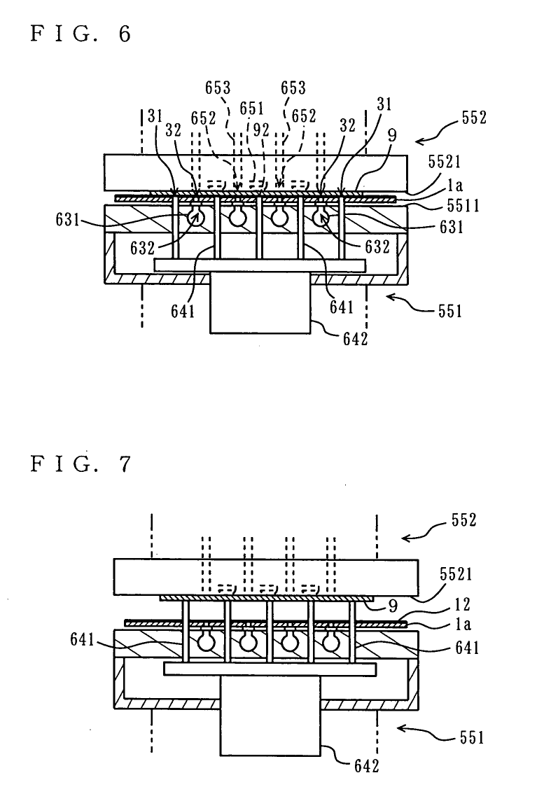

FIGS. 6 and 7 illustrate a manner in which the pickup mechanism 552 receives the FPC 9 from the pallet 1a. Air passages 631 are provided inside a lower portion of the retention mechanism 551. The passages 631 are in communication with openings 632 in a holding surface 5511 (i.e., an upper face). Inside the retention mechanism 551, push-up pins 641 for assisting in the peeling of the FPC 9 are provided. As the shaft 642 is elevated, the push-up pins 641 are caused to protrude from the holding surface 5511. The pallet 1a is positioned in place on the retention mechanism 551, on the basis of the positioning through holes 30a (see FIG. 1), so that the openings 632 coincide with the air outlets 32 of the pallet 1a and that the push-up pins 641 coincide with the through holes 31 (see FIGS. 1 and 2).

A holding surface 5521 (i.e., a lower face) of the pickup mechanism 552 has depressions 651 in order to avoid the electronic components 92 which are mounted on the FPC 9. Furthermore, suction apertures 652 for sucking the FPC 9 are formed in the holding surface 5521, with internal suction passages 653 being provided.

As shown in FIG. 6, when the pickup mechanism 552 receives the FPC 9, the holding surface 5521 of the pickup mechanism 552 is lowered until it abuts with the FPC 9. When air begins to be blown through the openings 632 in the retention mechanism 551, suction through the suction apertures 652 in the pickup mechanism 552 is also begun. As a result, the FPC 9 is partly peeled off the adhesive holding layer 12 of the pallet 1a. This process may be referred to as a “preliminary peeling process” of the FPC 9.

Next, as shown in FIG. 7, the shaft 642 of the retention mechanism 551 is elevated, and thus the push-up pins 641 pushes up the FPC 9. At this time, in synchronization with the movement of the push-up pins 641, the holding surface 5521 of the pickup mechanism 552 is elevated as shown in FIG. 7, so that the FPC 9 is completely peeled off the pallet 1a to be sucked onto the holding surface 5521 of the pickup mechanism 552. This process may be referred to as a “full peeling process” of the FPC 9.

From the above operation, even if the entire FPC 9 is adhered to the adhesive holding layer 12 of the pallet 1a, a large part of the FPC 9 is already peeled off by the action of air during the preliminary peeling process, the FPC 9 can be safely peeled off the pallet 1a, without an excessive force from the push-up pins 641 being applied to the FPC 9.

After the FPC 9 is peeled, the pallet 1a is carried by the conveyor 61 to the cleaning apparatus 56, as shown in FIG. 5. The cleaning apparatus 56 includes: a clean-up mechanism 561 for cleaning the pallet 1a; and a pallet moving mechanism 562 for moving the pallet 1a from an arriving end of the outgoing conveyor 61 to a leaving end of the incoming conveyor 62. The clean-up mechanism 561 extends cloth containing a detergent from a cloth roll 5611 around which the cloth is wound. A roller 5612 functions to ensure that the cloth is abutted against the adhesive holding layer 12 of the pallet 1a. Thereafter, the cloth is recovered by being wound onto a shaft 5613. Thus, the dust which is attached to the adhesive holding layer 12 is removed. The pallet 1a which has been thus cleaned is lowered by the pallet moving mechanism 562 to the conveyor 62, which carries the pallet 1a from the cleaning apparatus 56 to the loader apparatus 51. The pallet 1a is then moved onto the conveyor 61 by the pallet moving mechanism 514 of the loader apparatus 51.

As described above, the pallet 1a holds the entire FPC 9 with its adhesion ability so as to prevent the FPC 9 from peeling off the pallet 1a during the mounting of electronic components. Moreover, the first adhesive holding region 21, which holds the peripheral portion of the FPC 9 with a relatively low tackiness and the second adhesive holding region 22, which holds the central portion of the FPC 9 with a higher tackiness than that of the first adhesive holding region 21, facilitate the screen printing process. Furthermore, the use of blown air makes it possible to peel the FPC 9, which has electronic components mounted thereon, safely off the pallet 1a. Thus, the use of the pallet 1a facilitates the handling of the FPC 9 in the entire operation line related to mounting.

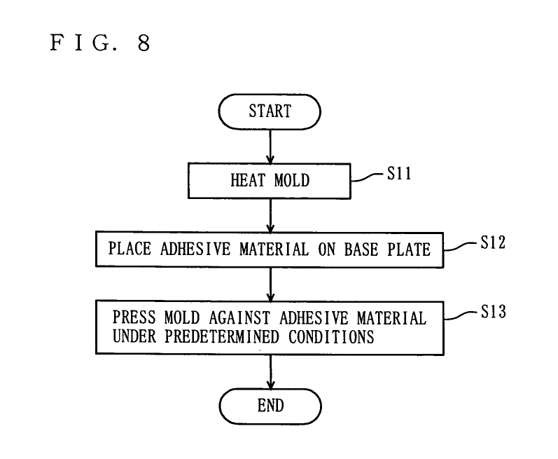

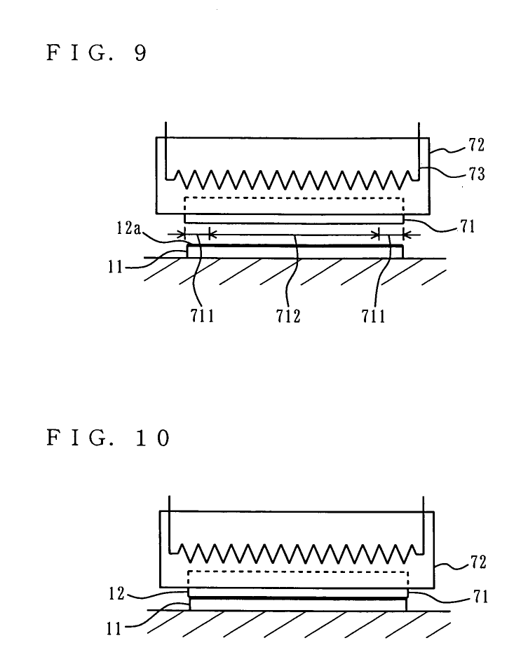

Next, a method for producing the pallet 1a will be described. FIG. 8 is a flowchart illustrating a flow of processes of producing the pallet 1a. FIGS. 9 and 10 illustrate the pallet 1a during production. As described above, the first adhesive holding region 21 and the second adhesive holding region 22 of the adhesive holding layer 12 of the pallet 1a are imparted with different tackinesses based on different surface coarsenesses. Accordingly, as shown in FIG. 9, a mold 71 which reflects the different surface coarsenesses of the first and second adhesive holding regions 21 and 22 is prepared, and attached to the pressing apparatus 72. In FIG. 9, an area indicated by the reference numeral 711 corresponds to the first adhesive holding region 21; and an area indicated by the reference numeral 712 corresponds to the second adhesive holding region 22. The pressing apparatus 72 is provided with a heater 73 for heating the mold 71 in advance (step S11).

Thereafter, an adhesive material 12a is placed on the base plate 11 (step S12). The adhesive material 12a may be composed of a rubber sheet, for example, or may be obtained by applying an adhesive material. Then, as shown in FIG. 10, the mold 71 is used to heat and press the adhesive material 12a with a predetermined temperature and force for a certain period of time, whereby an undulating pattern on the surface of the mold 71 is transferred to the adhesive material 12a. Thus, the adhesive holding layer 12 having the first adhesive holding region 21 and the second adhesive holding region 22 is formed (step S13). In this manner, the adhesive holding layer 12 having regions with different tackinesses can be easily formed. The mold 71 may further be provided with means for forming the aforementioned various holes in the pallet 1a concurrently with the formation of the adhesive holding layer 12.

Next, a method for producing the mold 71 having an undulating pattern corresponding to the first adhesive holding region 21 and the second adhesive holding region 22 will be described.

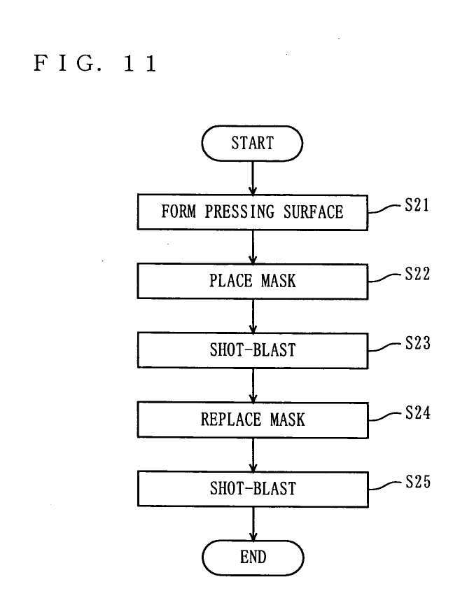

FIG. 11 is a flow chart illustrating a flow of processes of producing the mold 71 (note that while a typical exemplary mold 71 is illustrated, a number of variants are possible as described later). FIGS. 12 and 13 illustrate the mold 71 during production.

First, a mirror face which serves as a fundamental pressing surface 708 is formed on a main portion 70 of the mold 71 (step S21). Next, as shown in FIG. 12, a metal mask 709 is provided so as to oppose the pressing surface 708 (step S22). The mask 709 has an opening only in a region corresponding to the second adhesive holding region 22. Thereafter, by using a shot-blast apparatus, minute particles having a predetermined particle diameter are blasted against the pressing surface 708 in a direction shown by the arrows 81, with a predetermined velocity (step S23).

After the first shot-blast is completed, the mask 709 is replaced with another mask 713, as shown in FIG. 13 (step S24). The mask 713 has an opening only in a region corresponding to the first adhesive holding region 21. Then, minute particles having a particle diameter which is greater than that of the particles used in the first shot-blast are blasted against the pressing surface 708 in a direction shown by the arrows 82, with a predetermined velocity (step S25). As a result, an undulating pattern having a greater surface coarseness (i.e., presenting a more coarse surface) than that of the second adhesive holding region 22 is formed in a region of the pressing surface 708 corresponding to the first adhesive holding region 21. Alternatively, at step S25, minute particles having the same particle diameter as that of the particles used in step 23 may be used while altering the blasting velocity to obtain an undulating pattern with a depth which is different from that obtained in step S23.

By using a shot-blast technique in the aforementioned manner, a plurality of regions of different surface coarsenesses can be easily formed on the pressing surface 708.

Steps S22 and S23 may be omitted in the case where the tackier second adhesive holding region 22 is a mirror face. Further alternatively, an undulating pattern corresponding to the surface coarseness of the second adhesive holding region 22 may be formed during the process of step S21 of forming the pressing surface 708, thus omitting steps S22 and S23. In the case where regions of three or more different levels of surface coarseness are to be formed, steps S24 and S25 may be repeated.

As a technique which facilitates the formation of regions of different surface coarsenesses on the pressing surface 708, chemical etching may also be suitably used. In this case, a mirror-faced pressing surface 708 is first formed, and thereafter, an undulating pattern of predetermined characteristics is formed on the pressing surface 708 through chemical etching. The surface coarseness of the pressing surface 708 is appropriately determined so that an undulating pattern of predetermined characteristics can be provided on the surface of the adhesive holding layer for enabling adhesion ability adjustment.

(Second Embodiment)

Hereinafter, with reference to FIGS. 14 to 16, a substrate holder according to a second embodiment of the present invention will be described. As shown in FIG. 14, the substrate holder according to the present embodiment is also implemented as a pallet 1b, as is the case with the substrate holder according to the first embodiment. However, the pallet 1b according to the present embodiment is structured so that a plurality of discrete areas, each containing a less tacky first adhesive holding region 21 and tackier second adhesive holding regions 22, respectively hold a plurality of unit FPC pieces.

In FIG. 14, the regions of the surface of the base plate 11 which are not shown hatched are exposed. In other words, the adhesive holding layer is only formed in the first adhesive holding regions 21 and the second adhesive holding regions 22, which are shown with different types of oblique hatching. As shown in FIG. 14, a plurality of through holes 31 into which push-up pins are to be inserted are formed in each first adhesive holding region 21. A plurality of air outlets 32 are formed in each second adhesive holding region 22.

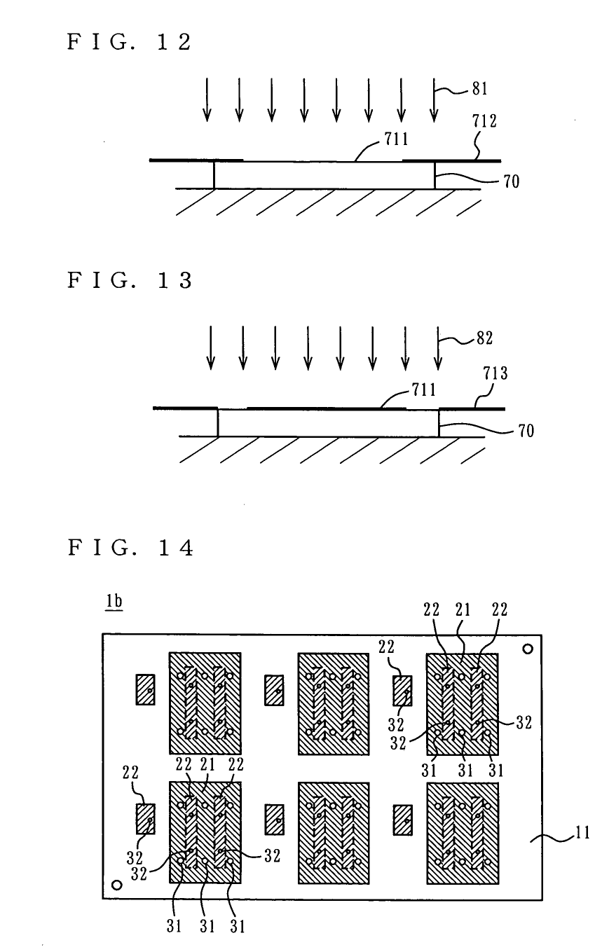

FIG. 15 shows an outer appearance of a unit FPC piece 91 to be held on the pallet 1b. The unit FPC piece 91 is configured so that a lead section 912 projects from an element section 911. Within the element section 911 are a mount region 91b in which an IC package is to be mounted and mount regions 91c in which resistors, capacitors, and the like are to be mounted.

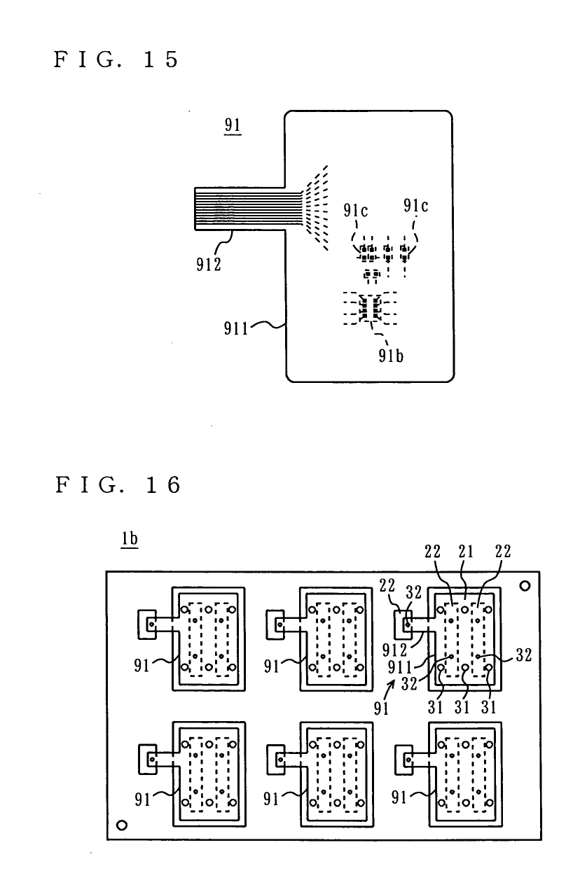

FIG. 16 illustrates a plurality of unit FPC pieces 91 being stuck to the pallet 1b. As shown in FIG. 16, the element section 911 of each unit FPC piece 91 is held on a discrete area which contains two second adhesive holding regions 22 confined within the first adhesive holding region 21. The tip of the lead section 912 is held by an islet of second adhesive holding region 22.

The manner of mounting electronic components on each unit FPC piece 91 on the pallet 1b is similar to the case of the pallet 1a shown in FIG. 1, except that a plurality of unit FPC pieces 91 are held on the pallet 1b. Each of the plurality of unit FPC pieces 91 is, almost in its entirety, stuck to the pallet 1b. As a result, the unit FPC pieces 91 are prevented from peeling off the pallet 1b during the mounting of electronic components. In particular, any peeling which starts in the lead section 912 of each unit FPC piece 91 is well prevented because the lead section 912 is held onto the tackier second adhesive holding regions 22. Since the region in which no unit FPC pieces 91 are retained is for the most part non-adhesive, screen printing can be facilitated.

The pallet 1b is constructed so that through holes 31 for receiving push-up pins are provided in each first adhesive holding region 21, and air outlets 32 are provided in each second adhesive holding region 22. Peeling of the unit FPC pieces 91 from the pallet 1b can be performed as follows. When air is blown through the air outlets 32, peeling first occurs in a large part of the tackier second adhesive holding regions 22. Thereafter, the push-up pins cause a mechanical peeling off the less tacky first adhesive holding region 21. As a result, peeling can be smoothly performed without an excessive force being applied to the unit FPC pieces 91. Thus, the unit FPC pieces 91 can be easily peeled although the second adhesive holding regions 22 retain a sufficient tackiness for holding the unit FPC pieces 91.

Since the element section 911 of each unit FPC piece 91 is held onto a discrete area which contains two second adhesive holding regions 22 confined within the first adhesive holding region 21, a smooth peeling of the unit FPC piece 91 can occur beginning in its peripheral portion (which is also true of the pallet 1a shown in FIG. 1). Furthermore, since there are no interspaces between the first adhesive holding region 21 and the second adhesive holding regions 22 which are present within such a discrete area of adhesive material, the element section 911 can be stably retained. Note that, in the case of the pallet 1a shown in FIG. 1, too, the entire upper face may be seen as a single area of adhesive material. Thus, by continuously providing two adhesive holding regions of different tackinesses on the same plane, the FPC can be retained by respectively different adhesion abilities, without causing deformation in the FPC. This allows electronic components and the like to be stably mounted in portions of the FPC corresponding to borders between the two types of adhesive holding regions.

The method for producing the pallet 1b, the mold to be used for producing the pallet 1b, and the method for producing such a mold are similar to those in the case of the pallet 1a shown in FIG. 1, except that the adhesive holding layer is to be provided only in certain portions of the surface of the base plate 11.

(Third Embodiment)

FIG. 17 illustrates a substrate holder according to a third embodiment of the present invention. As shown in FIG. 17, the substrate holder is implemented as a pallet 1c in the present embodiment. Similarly to the pallet 1a shown in FIG. 1, the pallet 1c includes a base plate 11 and an adhesive holding layer 12, except that a holding surface 121 of the pallet 1c is differentiated in level, so as to result in a higher-level region which corresponds to a less tacky first adhesive holding region 21, and a lower-level region which corresponds to a tackier second adhesive holding region 22. Alternatively, the higher-level region may be formed as a protruding portion with the lower-level region, or alternate stripes of higher-level regions and lower-level regions may be provided.

Similarly to the pallet 1b shown in FIG. 14, through holes 31 for receiving push-up pins 641 are provided in the first adhesive holding region 21, and air outlets 32 are provided in the second adhesive holding region 22. Through holes 31 for receiving push-up pins 641 are also provided in the second adhesive holding region 22.

As for an FPC 9 to be held on the pallet 1c, a reinforcement member 93 is glued to a face (i.e., the face that opposes the pallet 1c) of the FPC 9 opposite to the face on which electronic components 92 are mounted. Since the reinforcement member 93 has a thickness which is equal to the level difference in the holding surface 121, the FPC 9 can be held by the pallet 1c without the influence of the reinforcement member 93. The FPC 9 is stuck to the pallet 1c almost in its entirety, so that the FPC 9 is prevented from peeling off the pallet 1c during the mounting of electronic components. Peeling of the FPC 9 from the pallet 1c can be performed as follows. When air is blown through the air outlets 32, peeling first occurs in a large part of the tackier second adhesive holding region 22. Thereafter, the push-up pins cause a mechanical peeling. As a result, peeling can be smoothly performed without an excessive force being applied to the FPC 9.

The tackiness within the depression formed in the pallet 1c so as to avoid the reinforcement member 93, and the tackiness outside the depression may be appropriately set in accordance with the methodology of handling the FPC 9 and the strength characteristics of the FPC 9. For example, in the case where it is necessary to completely prevent the peeling of the FPC 9 during mounting, the tackiness of the higher-level region corresponding to the peripheral portion of the FPC 9 is set relatively high. If it is feared that the push-up pins 641 may leave scars on the FPC 9 due to strong adhesion of the reinforcement member 93, the tackiness of the lower-level region (i.e., interior of the depression) is set relatively low. Thus, in some applications, the region opposing the reinforcement member 93 may be the first adhesive holding region 21, whereas the other region may be the second adhesive holding region 22, instead of adopting the configuration shown in FIG. 17.

The method for producing the pallet 1c, the mold to be used for producing the pallet 1c, and the method for producing such a mold are similar to those in the case of the pallet 1a shown in FIG. 1, except that the aforementioned level difference in the holding surface 121 must be realized.

(Fourth Embodiment)

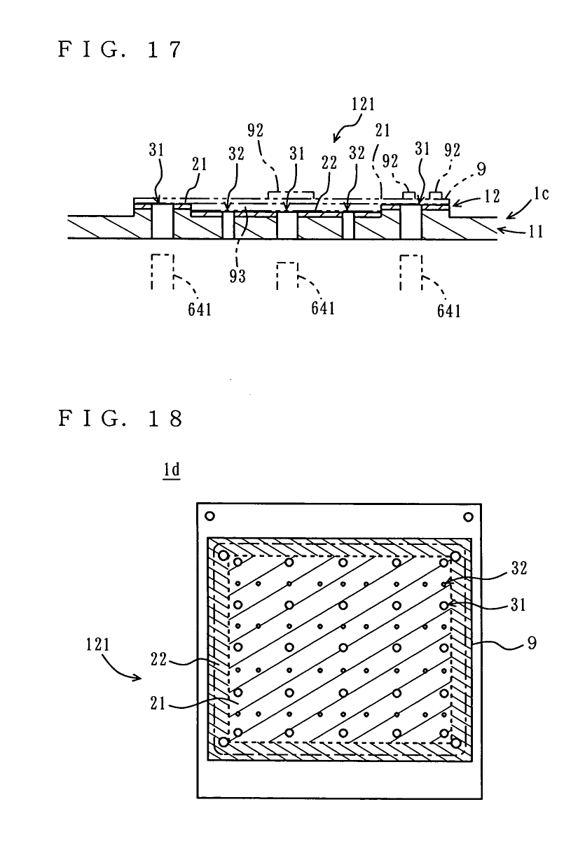

FIG. 18 illustrates a substrate holder according to a fourth embodiment of the present invention. As shown in FIG. 18, the substrate holder is implemented as a pallet 1d in the present embodiment. In the pallet 1d, the relationship between the first adhesive holding region 21 and the second adhesive holding region 22 is reversed from that in the pallet 1a shown in FIG. 1, so that the second adhesive holding region 22 surrounds the less tacky first adhesive holding region 21. However, a portion of the second adhesive holding region 22 lying outside the FPC 9 is kept to a minimum so that the screen mask will not strongly stick to the pallet 1d when printing solder paste.

In accordance with the pallet 1d, the peripheral portion of the FPC 9 is strongly prevented from peeling off the adhesive holding layer 12 during reflow, thus facilitating the handling of the FPC 9 during reflow. Thus, the tackiness of the portion of the adhesive holding region corresponding to the peripheral portion of the FPC 9 can be appropriately set to be higher or lower than that of the other region depending on the characteristics of the FPC 9 and the nature of the process during which the FPC 9 is to be held by the pallet.

The method for producing the pallet 1d, the mold to be used for producing the pallet 1d, and the method for producing such a mold are similar to those in the case of the pallet 1a shown in FIG. 1.

(Fifth Embodiment)

FIG. 19 illustrates a substrate holder according to a fifth embodiment of the present invention. As shown in FIG. 19, the substrate holder is implemented as a pallet le in the present embodiment. As shown in FIG. 19, the pallet le is configured so that a holding surface 121 of the adhesive holding layer 12 is differentiated in level similarly to the pallet 1c shown in FIG. 17, although the base plate 11 itself has a flat surface. The lower-level region is the less tacky first adhesive holding region 21, whereas the higher-level region is the tackier second adhesive holding region 22. Thus, the first adhesive holding region 21 and the second adhesive holding region 22 are formed as an integral piece. When the pallet 1e is viewed from above, the first adhesive holding region 21 would appear as the bottom of a depression surrounded by the second adhesive holding region 22.

Similarly to the pallet 1c shown in FIG. 17, through holes 31 for receiving push-up pins are provided in the first adhesive holding region 21 and the second adhesive holding region 22, and air outlets 32 are provided in the first adhesive holding region 21. As for an FPC 9 to be held on the pallet 1e, a reinforcement member 93 is glued to a face (i.e., the face that opposes the pallet 1e) of the FPC 9 opposite to the face on which electronic components 92 are mounted. Since the reinforcement member 93 has a thickness which is equal to the level difference in the holding surface 121, the FPC 9 can be held by the pallet 1e without the influence of the reinforcement member 93, thus improving the solder printing quality, for example. Since the FPC 9 is stuck to the pallet 1e almost in its entirety, the FPC 9 is prevented from peeling off the pallet 1e during the mounting of electronic components.

Peeling of the FPC 9 from the pallet 1e can be performed as follows. When air is blown through the air outlets 32, peeling first occurs in a large part of the first adhesive holding region 21. Thereafter, the push-up pins cause a mechanical peeling. As a result, peeling can be smoothly performed without an excessive force being applied to the FPC 9. Since the second adhesive holding region 22 surrounds the first adhesive holding region 21 which defines the bottom of the depression, the entire periphery of the FPC 9 is held by the tackier second adhesive holding region 22, thus preventing peeling of the FPC 9 during reflow and the like.

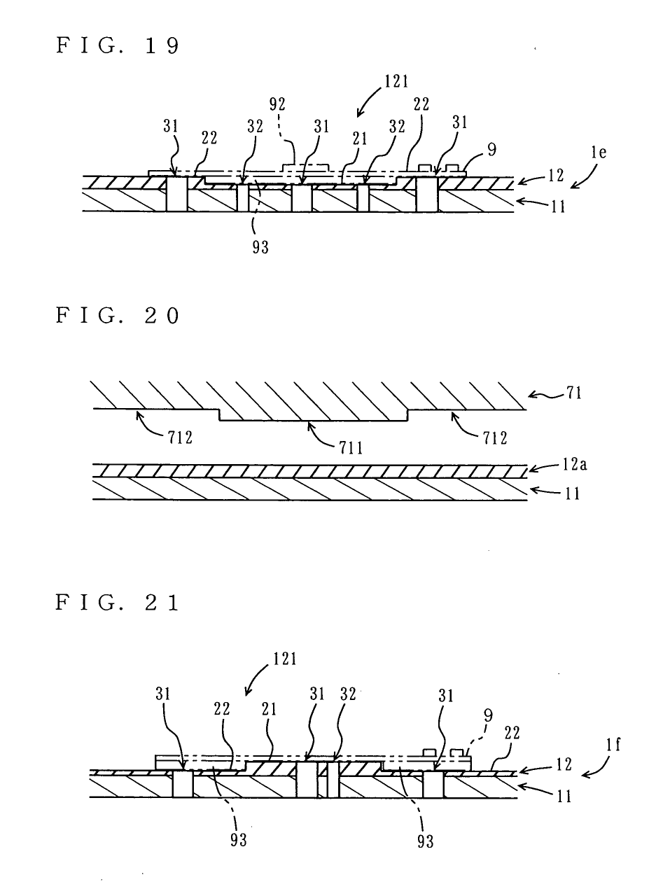

FIG. 20 illustrates a method of producing the pallet 1e by means of a mold 71. The mold 71 is differentiated in level so as to have a region 711 corresponding to the first adhesive holding region 21 and a region 712 corresponding to the second adhesive holding region 22. An undulating pattern corresponding to the first adhesive holding region 21 is formed in the region 711. In the region 712, an undulating pattern corresponding to the second adhesive holding region 22 (i.e., an undulating pattern which results in a smaller surface coarseness than that of the region 711) is formed.

When producing the pallet 1e, adhesive material 12a is attached to the base plate 11 so as to have a constant thickness, and then a press step is performed by means of the mold 71. Thus, the first adhesive holding region 21 and the second adhesive holding region 22 are formed on the adhesive material 12a with the intended respective undulating patterns and the intended level difference therebetween.

(Sixth Embodiment)

FIG. 21 illustrates a substrate holder according to a sixth embodiment of the present invention. As shown in FIG. 21, the substrate holder is implemented as a pallet 1f in the present embodiment. In the pallet 1f, a holding surface 121 of the adhesive holding layer 12 is differentiated in level so as to result in a higher-level region which corresponds to the less tacky first adhesive holding region 21 and a lower-level region which corresponds to the tackier second adhesive holding region 22. When the pallet 1f is viewed from above, the second adhesive holding region 22 would appear as surrounding the first adhesive holding region 21, such that the first adhesive holding region 21 constitutes an upper face of a protrusion from the second adhesive holding region 22.

Similarly to the pallet 1e shown in FIG. 19, through holes 31 for receiving push-up pins are provided in the first adhesive holding region 21 and the second adhesive holding region 22, and air outlets 32 are provided in the first adhesive holding region 21. As for an FPC 9 to be held on the pallet 1f, a reinforcement member 93 is glued to a face (i.e., the face that opposes the pallet if) of the FPC 9 opposite to the face on which electronic components 92 are mounted, substantially completely around the periphery of the FPC 9. Since the reinforcement member 93 has a thickness which is equal to the level difference in the holding surface 121, the FPC 9 can be held by the pallet 1f without the influence of the reinforcement member 93, thus improving the solder printing quality. Since the FPC 9 is stuck to the pallet 1f almost in its entirety, the FPC 9 is prevented from peeling off the pallet 1f during the mounting of electronic components.

Peeling of the FPC 9 from the pallet 1f can be performed as follows. When air is blown through the air outlets 32, peeling first occurs in a large part of the first adhesive holding region 21. Thereafter, the push-up pins cause a mechanical peeling. As a result, peeling can be smoothly performed without an excessive force being applied to the FPC 9. Since the second adhesive holding region 22 surrounds the first adhesive holding region 21 which constitutes an upper face of a protrusion from the second adhesive holding region 22, the entire periphery of the FPC 9 is held by the tackier second adhesive holding region 22, thus preventing peeling of the FPC 9 during reflow and the like.

The method for producing the pallet 1f is similar to that method illustrated with reference to FIG. 20, except for reversing the relationship between levels in the pressing surface of the mold. Through a press step, the first adhesive holding region 21 and the second adhesive holding region 22 are formed on the adhesive material 12a with the intended respective undulating patterns and the intended level difference therebetween.

Thus, the present invention has been described with reference to specific embodiments thereof. It will be appreciated that the present invention also permits various modifications, rather than being limited to the above embodiments.

For example, although the above-described pallets 1a to if are suitably used for holding a flexible circuit board, the circuit board to be held may alternatively be a highly stiff, plate-like circuit board (e.g., a glass epoxy or semiconductor circuit board).

It will be appreciated that adhesion-based retention of a circuit board is applicable not only to pallets for carrying purposes (e.g., 1a to if), but also to any type of substrate holder which may be used in the handling of circuit boards. Other than the field of electronic component mounting using solder paste or anisotropic conductive resin or the like, the aforementioned adhesion-based retention technique may also be used for holding a circuit board during any processing to which the circuit board is subjected.

The pallets 1a to 1f described in the above embodiments utilize an adhesive material which is provided on a base plate 11. Alternatively, for example, the substrate holder according to the present invention may be produced by processing a single adhesive member. In this case, there will be no adhesive holding layer, and the main portion of the substrate holder will be composed of the same material that composes the holding surface.

The first adhesive holding region 21 and the second adhesive holding region 22 may be respectively formed on the surfaces of different adhesive materials. However, it is preferable that the first and second adhesive holding regions 21 and 22 are both on the surface of the same adhesive material in order to facilitate the formation thereof. Although each of the above embodiments illustrates the use of two types of adhesive holding regions, three or more types of adhesive holding regions may also be used. Furthermore, there is no need for clear boundaries between such adhesive holding regions; for example, a holding surface having gradually changing tackiness may be formed so as to obtain different tackinesses at different points on the holding surface.

Although the above embodiments illustrate examples where tackiness is adjusted based on surface coarseness, the tackiness adjustment may instead be achieved by varying the undulation features present on the adhesive surface (e.g., sharp protrusions and round protrusions). That is, tackiness differentiation may be obtained by altering the characteristics of the undulating patterns used for tackiness adjustment.

The adhesive material is not limited to silicone rubber or polyurethane rubber, and any other suitable material may be used. One example of a suitable material is fluorine rubber. Since fluorine rubber has a high releasability, its surface might be mirror-faced in practical use for an improved adhesiveness (or an improved closeness of contact), and the surface tackiness of fluorine rubber may be adjusted by forming minute grooves on the mirror-faced surface. In the case where silicone rubber is used, siloxane gas may be generated due to heating, possibly affecting the circuit board due to a deposition of insulative siloxane. Use of fluorine rubber can avoid the problem of siloxane generation.

As described above, the present invention is applicable to, for example, an automated production line for realizing automatic mounting of electronic components or the like on a sheet-shaped flexible printed circuit board.

While the invention has been described in detail, the foregoing description is in all aspects illustrative and not restrictive. It is understood that numerous other modifications and variations can be devised without departing from the scope of the invention.

What is claimed is:

1. A substrate holder for holding a circuit board, comprising:
a main body; and
a holding surface formed on the main body for allowing a circuit board to adhere to the holding surface,
wherein the holding surface includes:
a first adhesive holding region for holding the circuit board with a first tackiness; and
a second adhesive holding region for holding the circuit board with a second tackiness which is different from the first tackiness, such that the first and second adhesive holding regions hold the circuit board in cooperation.

2. The substrate holder according to claim 1, further comprising an adhesive material provided on the main body,
wherein the first adhesive holding region and the second adhesive holding region are on a surface of the adhesive material.

3. The substrate holder according to claim 2, wherein
the first adhesive holding region and the second adhesive holding region are within one area of the adhesive material provided on the main body.

4. The substrate holder according to claim 2 or 3, wherein,
the first adhesive holding region and the second adhesive holding region are composed of the same adhesive material, and
the first adhesive holding region and the second adhesive holding region are imparted with different surface undulation characteristics.

5. The substrate holder according to claim 4, wherein
the first adhesive holding region and the second adhesive holding region have different surface coarsenesses.

6. The substrate holder according to any of claims 1 to 5, wherein
the first adhesive holding region and the second adhesive holding region are provided within one plane.

7. The substrate holder according to any of claims 1 to 5, wherein
the first adhesive holding region and the second adhesive holding region are differentiated in level.

8. The substrate holder according to claim 7, wherein
one of the first and second adhesive holding regions surrounds the other adhesive holding region, and the other adhesive holding region projects from the one adhesive holding region.

9. The substrate holder according to claim 7, wherein
a bottom of a depression surrounded by one of the first and second adhesive holding regions comprises the other adhesive holding region.

10. The substrate holder according to any of claims 1 to 7, wherein,
the first tackiness is less than the second tackiness, and
the second adhesive holding region is confined within the first adhesive holding region.

11. The substrate holder according to any of claims 1 to 10, wherein
the first tackiness is less than the second tackiness, and
a through hole for receiving a pin is provided in the first adhesive holding region, the pin being used when peeling off the circuit board.

12. The substrate holder according to claim 11, wherein
an air outlet is provided in the second adhesive holding region.

13. The substrate holder according to any of claims 1 to 7, wherein
the first tackiness is less than the second tackiness, and
the first adhesive holding region is confined within the second adhesive holding region.

14. The substrate holder according to any of claims 1 to 13, wherein
the holding surface includes a plurality of sets of the first adhesive holding region and the second adhesive holding region.

15. A substrate holder for holding a flexible circuit board, comprising:
a main body; and
an adhesive material formed on the main body for allowing a circuit board to adhere to the adhesive material,
wherein an undulating pattern for tackiness adjustment is provided on a surface of the adhesive material.

16. The substrate holder according to claim 2 or 15, wherein
the adhesive material is silicone rubber, polyurethane rubber, or fluorine rubber.

17. The substrate holder according to any of claims 1 to 16 being used as a pallet for carrying the circuit board.

18. A method for producing a substrate holder for holding a circuit board, comprising the steps of:
placing an adhesive material on a main body to become the substrate holder; and
pressing a mold against the adhesive material while heating the mold, the mold having an undulating pattern for tackiness adjustment provided thereon.

19. The method according to claim 18, wherein
the mold includes a region in which a first undulating pattern is formed and a region in which a second undulating pattern is formed.

20. The method according to claim 19, wherein,
the mold is differentiated in level between the region in which the first undulating pattern is formed and the region in which the second undulating pattern is formed.

21. A method for producing a mold to be used for forming an undulating pattern for tackiness adjustment on an adhesive material of a substrate holder for holding a circuit board, comprising the steps of:
forming a pressing surface of the mold; and
blasting minute particles against the pressing surface.

22. The method according to claim 21, further comprising, before the step of blasting minute particles:
a step of placing a mask so as to oppose the pressing surface.

23. The method according to claim 21 or 22, further comprising, after the step of blasting minute particles:
a step of placing a mask so as to oppose the pressing surface; and
blasting another type of minute particles against the pressing surface through the mask.

24. A method for producing a mold to be used for forming an undulating pattern for tackiness adjustment on an adhesive material of a substrate holder for holding a circuit board, comprising the steps of:
forming a pressing surface of the mold; and
forming an undulating pattern on the pressing surface by chemical etching.
